(19) United States
(12) Patent Application Publication
(10) Pub. No.: US 2025/0130275 A1
(43) Pub. Date: Apr. 24, 2025

(54) SEMICONDUCTOR BURN-IN MACHINE COOLING SYSTEM

(71) Applicant: Micro Control Company, Fridley, MN (US)

(72) Inventor: Aidan Michael Fawcett, Minneapolis, MN (US)

(21) Appl. No.: 18/826,842

(22) Filed: Sep. 6, 2024

Related U.S. Application Data
(60) Provisional application No. 63/592,488, filed on Oct. 23, 2023.

(51) Int. Cl. G01R 31/28; H05K 7/20

(52) U.S. Cl. CPC G01R 31/2877; G01R 31/2863; G01R 31/287; H05K 7/20272

(57) ABSTRACT

A semiconductor burn-in board includes a testing board and a board cooling system. The testing board includes a plurality of device testing units, each configured to apply test signals to a received semiconductor device and including a thermal head, and a testing stage connector, through which the test signals are communicated to the device testing units, located adjacent a back edge of the testing board and facing in a rearward direction. The board cooling system includes a liquid input including an input fitting oriented in the rearward direction and a check valve, a liquid output including an output fitting oriented in the rearward direction and a check valve, and a fluid circuit including a plurality of fluid pathways configured to deliver a flow of liquid received at the liquid input through the thermal heads and to the liquid output.

### CROSS-REFERENCE TO RELATED APPLICATION

The present application is based on and claims the benefit of U.S. provisional patent application Ser. No. 63/592,488, filed Oct. 23, 2023, the content of which is hereby incorporated by reference in its entirety.

### BACKGROUND

Semiconductor devices, such as silicon integrated circuit chips or other semiconductor devices, are subject to early failure during their life cycle. It is desirable to detect and eliminate the devices that are most prone to early failure prior to sending them to market. Additionally, it is desirable to identify the components of the semiconductor devices that cause the early failures so that they may be improved. Thus, producers of these devices have found it cost-effective to utilize burn-in systems to rigorously temperature stress the semiconductor devices while simultaneously powering them in order to test the reliability of the devices.

Semiconductor burn-in systems typically include a semiconductor burn-in machine having a testing chamber that houses a plurality of burn-in boards, each of which supports a number of device testing units that receive semiconductor devices to be tested. The device testing units power the semiconductor devices and expose the devices to operational stress (e.g., heat stress, power stress, etc.) over an extended period of time. Heat exchange systems are employed to maintain the devices within a desired temperature range during testing. Such systems generally include a cooling system that circulates cooling liquid through thermal heads of the device testing units.

Examples of such semiconductor burn-in systems are described in U.S. Pat. Nos. 7,288,951 and 7,650,762, which issued to Micro Control Company and are incorporated herein by reference in their entirety.

### SUMMARY

Embodiments of the present disclosure generally relate to cooling systems used to maintain semiconductor devices within a desired temperature range during testing of the devices and, more specifically to semiconductor burn-in boards, semiconductor burn-in systems, and various methods.

One embodiment of a semiconductor burn-in board that is configured for insertion into a chamber of a semiconductor burn-in machine includes a testing board and a board cooling system. The testing board includes a plurality of device testing units, each configured to apply test signals to a received semiconductor device and including a thermal head, and a testing stage connector, through which the test signals are communicated to the device testing units, located adjacent a back edge of the testing board and facing in a rearward direction. The board cooling system includes a liquid input including an input fitting oriented in the rearward direction and a check valve, a liquid output including an output fitting oriented in the rearward direction and a check valve, and a fluid circuit including a plurality of fluid pathways configured to deliver a flow of liquid received at the liquid input through the thermal heads and to the liquid output.

One embodiment of a semiconductor burn-in system includes a semiconductor burn-in machine and a plurality of burn-in boards. The semiconductor burn-in machine includes a housing including a chamber having an opening at a front end and a rear end that is opposite the front end, a plurality of testing board connectors, each located at the rear end of the chamber and oriented in a forward direction, which is toward the front end, and a plurality of liquid connectors. Each liquid connector includes a source fitting at the rear end oriented in the forward direction, and a return fitting at the rear end oriented in the forward direction. Each of the burn-in boards is configured to be installed in the chamber through the opening and includes a testing board and a board cooling system. The testing board includes a plurality of device testing units, each configured to apply test signals to a received semiconductor device under test and including a thermal head, and a testing stage connector located adjacent a back edge of the testing board and oriented in a rearward direction that is opposite the forward direction, the testing stage connector configured deliver the test signals to the device testing units. The board cooling system includes a liquid input including an input fitting oriented in the rearward direction and a check valve, a liquid output including an output fitting oriented in the rearward direction and a check valve, and a fluid circuit including a plurality of fluid pathways configured to deliver a flow of liquid received at the liquid input through the thermal heads and to the liquid output.

Aspects of the present disclosure are directed to methods relating to a semiconductor burn-in system, which includes a semiconductor burn-in machine and a burn-in board. The semiconductor burn-in machine includes a housing including a chamber having an opening at a front end and a rear end that is opposite the front end, a plurality of testing board connectors, each located at the rear end of the chamber and oriented in a forward direction, which is toward the front end, and a plurality of liquid line connectors. Each liquid line connector includes a source fitting at the rear end oriented in the forward direction, and a return fitting at the rear end oriented in the forward direction. The burn-in board includes a testing board and a board cooling system. The testing board includes a plurality of device testing units, each configured to apply test signals to a received semiconductor device under test and including a thermal head, and a testing stage connector located adjacent a back edge of the testing board and oriented in a rearward direction that is opposite the forward direction, the testing stage connector configured deliver the test signals to the device testing units. The board cooling system includes a liquid input including an input fitting oriented in the rearward direction and a check valve, a liquid output including an output fitting oriented in the rearward direction and a check valve, and a fluid circuit configured to deliver a flow of liquid received at the liquid input through the thermal heads and to the liquid output. In a method of installing the burn-in board in the chamber of the housing, the burn-in-board is moved in the rearward direction through the opening and toward the rear end. In response to this movement of the burn-in board the testing stage connector is mated to the testing board connector, the input fitting is mated to the source fitting, and the output fitting is mated to the return fitting.

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter. The claimed subject matter is not limited to implementations that solve any or all disadvantages noted in the Background.

### BRIEF DESCRIPTION OF THE DRAWINGS

FIG. 1 is a simplified diagram of an example of a semiconductor burn-in system that includes an example of a semiconductor burn-in machine for testing semiconductor devices, in accordance with embodiments of the present disclosure.

FIG. 2 is a simplified top view of an example of a semiconductor burn-in machine, in accordance with embodiments of the present disclosure.

FIG. 3 is an isometric view of a front end of a portion of an example of the semiconductor burn-in machine, in accordance with embodiments of the present disclosure.

FIG. 4 is a simplified block diagram of an example of a semiconductor burn-in system, in accordance with embodiments of the present disclosure.

FIG. 5 is a simplified top view of an example of a semiconductor burn-in machine, in accordance with the prior art.

FIGS. 6A and 6B are simplified top views of an example of a semiconductor burn-in system and a semiconductor burn-in machine, respectively illustrating a semiconductor burn-in board in an installed or connected state and a disconnected or deinstalled state, in accordance with embodiments of the present disclosure.

FIG. 7 is an isometric exploded view of an example of a semiconductor burn-in board, in accordance with embodiments of the present disclosure.

FIG. 8 is an isometric view of an example of a testing board with device testing units exploded, in accordance with embodiments of the present disclosure.

FIG. 9 is a simplified side view of a portion of an example of a semiconductor burn-in board, in accordance with embodiments of the present disclosure.

FIG. 10 is a schematic diagram of an example of a cooling system, in accordance with embodiments of the present disclosure.

FIGS. 11A and 11B are simplified cross-sectional views of an example pair of cooperative male and female fittings, in accordance with embodiments of the present disclosure.

FIG. 12 is a flowchart illustrating a method of installing a semiconductor burn-in board in a semiconductor burn-in machine, in accordance with embodiments of the present disclosure.

FIG. 13 is a flowchart illustrating a method of operating a semiconductor burn-in machine, in accordance with embodiments of the present disclosure.

FIG. 14 is a flowchart illustrating a liquid blowout operation, in accordance with embodiments of the present disclosure.

FIG. 15 is a simplified diagram of an example of a controller, in accordance with embodiments of the present disclosure.

### DETAILED DESCRIPTION OF ILLUSTRATIVE EMBODIMENTS

Embodiments of the present disclosure are described more fully hereinafter with reference to the accompanying drawings. Elements that are identified using the same or similar reference characters refer to the same or similar elements. The various embodiments of the present disclosure may, however, be embodied in many different forms and should not be construed as limited to the embodiments set forth herein. Rather, these embodiments are provided so that this disclosure will be thorough and complete, and will fully convey the scope of the present disclosure to those skilled in the art.

Specific details are given in the following description to provide a thorough understanding of the embodiments. However, it is understood by those of ordinary skill in the art that the embodiments may be practiced without these specific details. For example, circuits, systems, networks, processes, frames, supports, connectors, motors, processors, and other components may not be shown, or may be shown in block diagram form in order to not obscure the embodiments in unnecessary detail.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

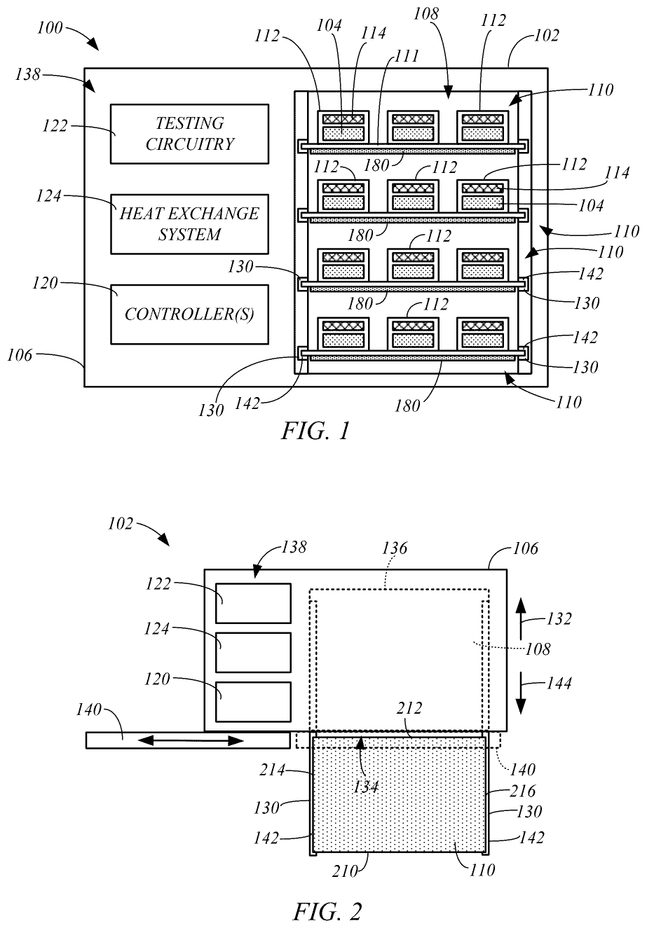

FIG. 1 is a simplified diagram of an example of a semiconductor burn-in system 100 that includes a semiconductor burn-in machine 102 for testing semiconductor devices 104, in accordance with embodiments of the present disclosure. The burn-in machine 102 includes a housing 106 having a burn-in chamber 108 that is configured to receive one or more burn-in boards or burn-in board assemblies 110 formed in accordance with embodiments of the present disclosure.

Each burn-in board 110 includes a testing board 111 that includes a testing stage having a plurality of device testing units 112. Each testing unit 112 includes a socket that receives one of the devices 104 and is used to perform conventional testing operations on the received device 104 while maintaining the device 104 within a desired temperature range using a thermal head 114. Any suitable device testing unit 112 may be used, such as those produced by Enplas Corporation and Yamaichi Electronics Company, Limited for example.

The system 100 also comprises one or more controllers 120 for controlling functions described herein, testing circuitry 122 and a heat exchange system 124. The testing circuitry 122 generally facilitates the performance of conventional testing operations on the devices 104 using the device testing units 112, while the heat exchange system 124 operates to maintain the devices 104 within a desired temperature range during testing using the thermal heads 114.

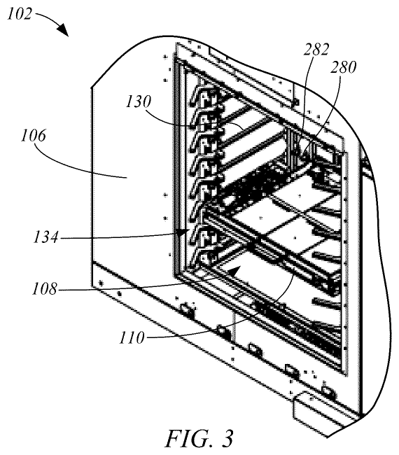

FIG. 2 is a simplified top view of the burn-in machine 102 shown in FIG. 1 with a burn-in board 110 substantially positioned outside the burn-in chamber 108, in accordance with embodiments of the present disclosure. FIG. 3 is an isometric view of a front end of a portion of an example of the machine 102, in accordance with embodiments of the present disclosure.

The burn-in chamber 108 includes guides 130 that are positioned along sidewalls of the chamber 108. Opposing pairs of the guides 130 are configured to support the burn-in boards 110, as indicated in FIGS. 1 and 3. Installation of a burn-in board 110 in the machine 102 generally involves guided movement of the burn-in board 110 in a rearward direction 132 through an opening 134 in the chamber 108 using the guides 130 until connectors of the burn-in board 110 mate with corresponding connectors of the machine 102. The connectors of the machine are generally supported by a rear wall 136 (e.g., insulated wall, backplane, etc.) of the housing 106 that separates the burn-in chamber 108 from an electronics section 138 that may contain one or more of the controllers 120, components of the testing circuitry 122, and components of the heat exchange system 124, for example, as indicated in FIG. 2. The final stages of the rearward movement of the burn-in board 110 during installation may be controlled using conventional techniques to ensure that the force that is applied between the connectors does not exceed a threshold force at which the connectors could be damaged. Once the burn-in boards 110 are installed in the chamber 108, a door 140 (FIG. 2) may be positioned to cover the opening 134, as indicated in phantom lines.

In one embodiment, the guides 130 comprise pairs of slide rails 142 that are configured to extend through the front opening 134 of the chamber 108, as indicated in FIG. 2. The slide rails 142 may be attached to side walls of the chamber 108 or supported by a frame that is mounted within the chamber 108, for example.

The slide rails 142 simplify the installation of the burn-in boards 110 in the machine 102 by allowing an operator to mount each burn-in board 110 to a pair of the slide rails 142 while they are fully extended through the opening 134 as shown in FIG. 2, rather than having to manually feed the burn-in board 110 to fixed side rails of the chamber 108. The slide rails 142 assist in guiding movement of the burn-in board in the rearward direction 132 while aligning the connectors of the board with the corresponding connectors at the rear wall 136 during installation of the board 110, and in the forward direction 144 during removal or deinstallation of the board 110 from the chamber 108. Additionally, the slide rails 142 enable an operator to inspect or perform maintenance on the burn-in boards 110 while they are supported by the slide rails 142 in their extended position (FIG. 2), rather than having to completely remove the burn-in boards 110 from the machine 102 and move them to another location for inspection or maintenance.

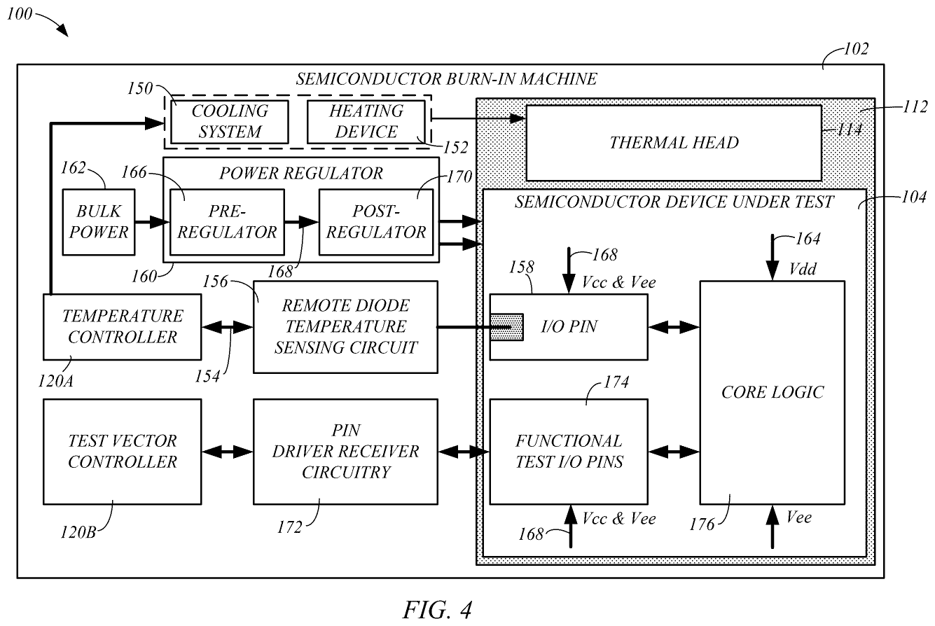

FIG. 4 is a simplified block diagram of an example of a burn-in system 100, in accordance with embodiments of the present disclosure. Many of the depicted elements are conventional for burn-in systems and, thus, a detailed explanation of each element is unnecessary.

The heat exchange system 124 may include a cooling system 150 that supplies cooling liquid to the thermal head 114 to maintain the devices 104 under test within a desired temperature range and prevent the devices 104 from overheating. In some embodiments, the heat exchange system 124 includes heating devices 152, such as heating elements within the thermal heads 114, that may be used to maintain the temperature of the devices 104 within a desired temperature range. The heat exchange system 124 may include a temperature controller 120A that controls the cooling system 150 and/or the heating devices 152 in response to a temperature output signal 154 from a temperature sensing circuit 156 that senses or obtains a temperature of the device 104, such as through a pin 158 of the device 104, for example.

The machine 102 generally converts incoming power (e.g., 480 VAC) to bulk power 162 (e.g., 4000 W at 44 VDC). The testing circuitry 122 includes a power regulator 160 that converts the bulk power 162 to test power 164 (e.g., 4000 W) having a voltage that is usable by the testing stage of the testing board 111 to power the device testing units 112. In some embodiments, the power regulator 160 includes a pre-regulator 166 that is configured to convert the bulk power 162 to main power 168 having a voltage of about 7-12 VDC, and a post-regulator 170 comprising a plurality of power supplies that convert the main power 168 to the test power 164. The main power 168 may be supplied to the testing stage as a positive supply voltage Vcc (e.g., 7-12 VDC) and a negative supply voltage Vee (e.g., electrical ground), and the testing power 164 may be provided to the testing stage as a logic positive supply voltage Vdd (e.g., 0.5-3.0 or 0.5-4.0 VDC), for example.

The testing circuitry 122 may include a test vector controller 120B and pin driver receiver circuitry 172, that are used to perform various functional tests on the device 104 through a set of functional test I/O pins 174. The functional tests determine whether components of the semiconductor device 104, such as core logic 176 and/or other components, are operating properly during the testing period.

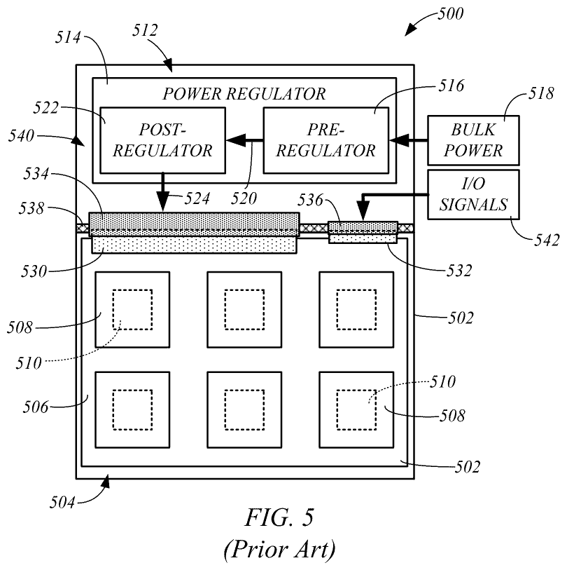

FIG. 5 is a simplified top view of a burn-in machine 500, in accordance with the prior art. The machine 500 includes many of the features described above, such as a housing 502 that includes a burn-in chamber 504, in which burn-in boards 506 are received. Each burn-in board 506 includes a plurality of device testing units 508 that perform testing operations on semiconductor devices 510. The housing 502 also includes an electronics section 512 that supports or contains machine electronics, such as a power regulator 514. As discussed above, the power regulator 514 includes a pre-regulator 516 that converts bulk power 518 (e.g., 4000 W at 44 VDC) into main power 520 (e.g., 4000 W at 12 VDC) and a post-regulator 522 that converts the main power 520 to test power 524 that includes logic power having a voltage of approximately 0.5-3.0 VDC.

Each burn-in board 506 includes a power connector 530 and a testing stage connector 532 that are respectively configured to mate with corresponding connectors 534 and 536 of the machine 500 when the burn-in board 506 is fully received within the chamber 504, as generally shown in FIG. 5. The connectors 534 and 536 may be attached to a rear wall (e.g., insulated wall, backplane) 538 of the housing 502 that may separate the electronics section 512 containing the power regulator 514 from the burn-in chamber 504. The test power 524 is delivered to the burn-in board 506 through the mated power connectors 530 and 534 and input/output signals 542 (e.g., test signals, measured results, etc.) are communicated through the mated testing stage connectors 532 and 536.

As mentioned above, the test power 524 delivered by the post-regulator 522 may be around 4000 W and have a voltage ranging from 0.5-3.0 VDC. The test power 524 may be generated by multiple power supplies and delivered through corresponding pins of the connectors 530 and 534. Thus, in one example, the current delivered through each pair of pins (e.g., 16 pairs of pins) of the power connectors 530 and 534 may reach around 125 A. Safe handling of such high power and high current requires very robust power connectors 530 and 534, and associated cabling and infrastructure. The robust power connectors 530 and 534 are generally large and take up valuable space within the machine 500. Additionally, the robust power connectors 530 and 534 can complicate the proper seating of a burn-in board 506 within the chamber 508, such as by requiring a greater force to fully connect the power connectors 530 and 534, for example. Some embodiments of the present disclosure eliminate the need for the robust power connectors 530 and 534 and provide other advantages over prior art semiconductor burn-in machines, such as machine 500.

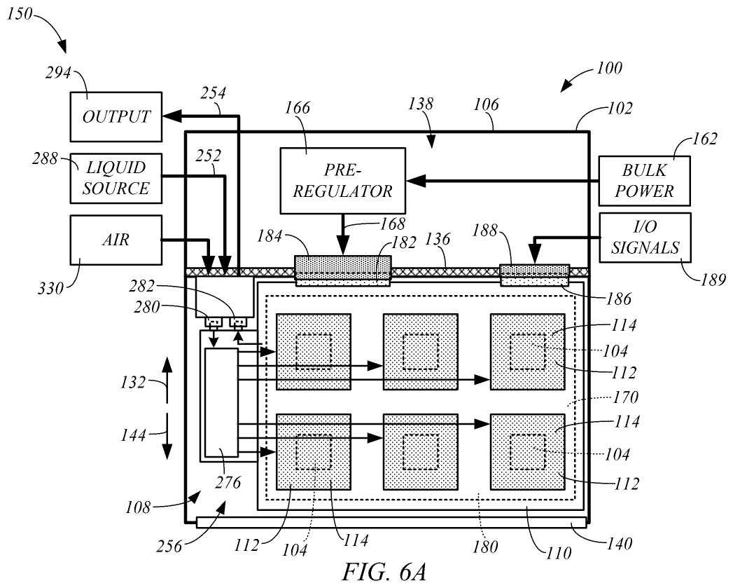

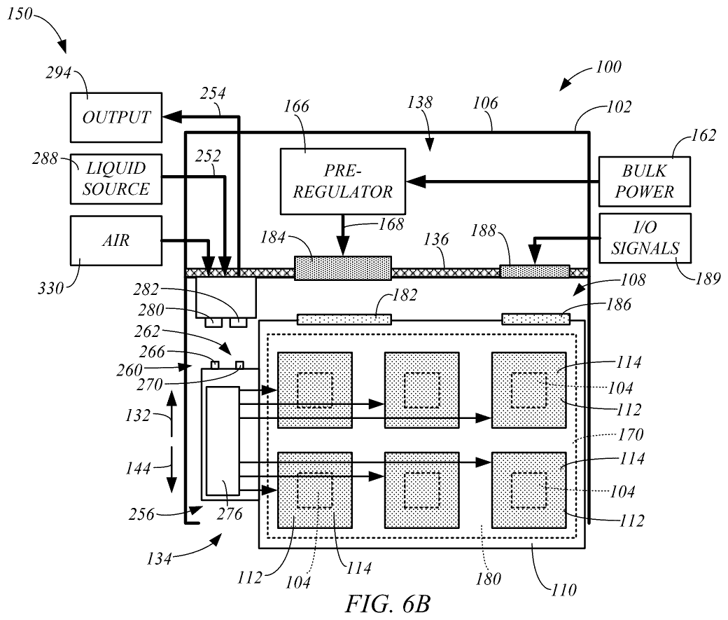

FIGS. 6A and 6B are simplified top views of an example of the system 100 and a semiconductor device burn-in machine 102, in accordance with embodiments of the present disclosure, respectively illustrating a burn-in board 110 in an installed or connected state and a disconnected or deinstalled state. In general, the machine 102 moves the post-regulator 140 from the electronics section 138 of the housing 106 to a power regulator board 180 of the burn-in board 110, as indicated in FIG. 1 and in phantom lines in FIGS. 6A and 6B.

A power connection between the pre-regulator 166 and the post-regulator 170 may be formed by mating a burn-in board main power connector 182 to a machine power connector 184, as indicated in FIG. 6A. The machine power connector 184 may be attached to a rear wall (e.g., insulated wall, backplane, etc.) 136 that divides the chamber 108 from the electronics section 138. A testing stage connector 186 of the burn-in board is configured to connect to a corresponding machine testing stage connector 188, which may be supported by the wall 136, to facilitate communication of input/output signals 189, such as to the functional test I/O pins 174 (FIG. 4), for example. Accordingly, when the burn-in board 110 in the disconnected or deinstalled state (FIG. 6B) is moved through the opening 134 to the chamber 108 in the rearward direction 132 and fully received in the chamber 108, such as under the assistance of the slide rails 142 (FIGS. 1 and 2), the power connectors 182 and 184 and the testing stage connectors 186 and 188 mate together, as shown in FIG. 6A.

As a result, rather than having to supply the high-current test power 164 from the post-regulator 170 through the power connection between the burn-in board 110 and the machine electronics as in the machine 500 (FIG. 5), the relatively low current (e.g., 86 A) main power 168 (e.g., 4 kW) is delivered from the pre-regulator 166 to the burn-in board 110 through the connectors 182 and 184. The main power 168 may also be delivered through a reduced number of pairs of pins of the connectors 182 and 184, such as 6 pairs, each delivering up to 86 A, rather than the 16 pairs of pins that each deliver up to 125 A, as with the prior art machine 500, for example. As a result, the machine 102 is able to deliver the high power required for performing high power and high-current testing of semiconductor devices 104, while reducing the magnitude of the current passing through the power connectors 182 and 184 of the burn-in board 110 and the machine 102.

Accordingly, the robust power connectors 530 and 534 of the prior art machine 500 may be replaced with a main power connector 182 of the burn-in board 110 and the cooperating power connector 184 of the machine 102 that are smaller and less robust. This reduces costs and can simplify the process of mating the connectors (e.g., lower force). The reduction of the pathways through which the high current power must travel between the machine 102 and the burn-in board 110 results in lower heat production and greater safety for operators.

In some embodiments, the burn-in board 110 comprises an assembly of the power regulator board 180 and the device testing board 111, as indicated in FIG. 1. As mentioned above, the power regulator board 180 comprises the post-regulator 170 and the testing board 111 comprises the device testing units 112 and corresponding circuitry that is typically found in conventional burn-in boards.

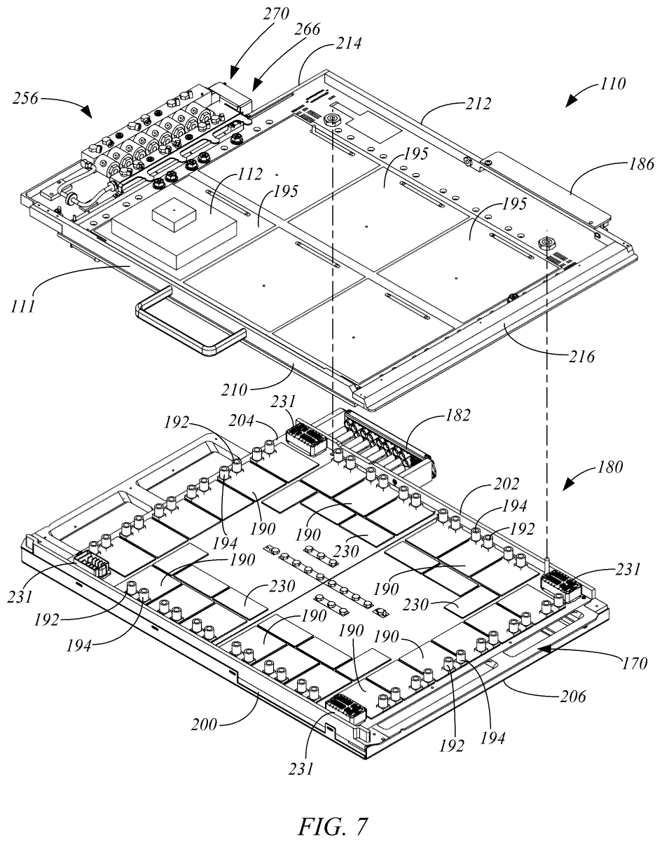

FIG. 7 is an isometric exploded view of an example of the burn-in board 110 and FIG. 8 is an isometric view of an example of the testing board 111, in accordance with embodiments of the present disclosure. FIGS. 7 and 8 each illustrate a single device testing unit on the testing board 111.

In some embodiments, the power regulator board 180 includes the main power connector 182 that is configured to receive the main power 168 from the pre-regulator of the machine electronics through pairs of positive and negative (electrical ground) connector pins. The power regulator board 180 also includes a plurality of power supplies 190 that receive the main power 168 from the connector 182 through suitable cabling or conductive pathways and convert the main power 168 into the test power 164. The test power 164 from each power supply 190 is fed to the device testing board 111 through a pair of test power connectors 192 and 194 (positive and negative or electrical ground). Control signals for controlling the power supplies 190 and their test power output may be provided through pins of the main power connector 182 or a separate connector.

The testing board 111 includes a plurality of conventional device testing units 112, such as six testing units 112, as shown in FIGS. 6A and 6B. The testing board 111 may include a pad 195 for each testing unit 112, as indicated in FIGS. 7 and 8. The testing board 111 also includes the testing stage connector 186 through which input/output signals (e.g., test signals) are communicated to the device testing units 112. Circuitry of the testing board 111 provides conductive pathways for routing the test power 164 from one or more of the power supplies 190 (FIG. 7) to each testing socket through the corresponding test power connectors 192 and 194. The device testing units 112 may be conventional units that are each configured to perform testing operations on a semiconductor device 104 received in a socket of the device testing unit 112 using the test power and the test signals.

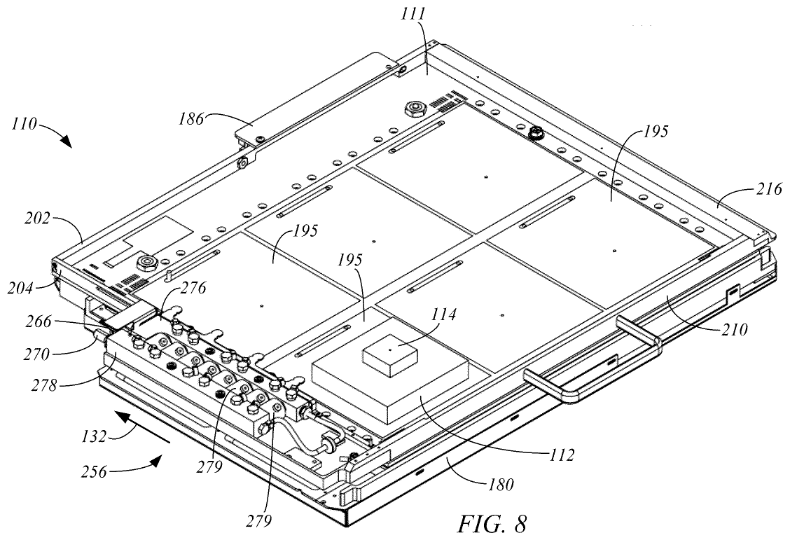

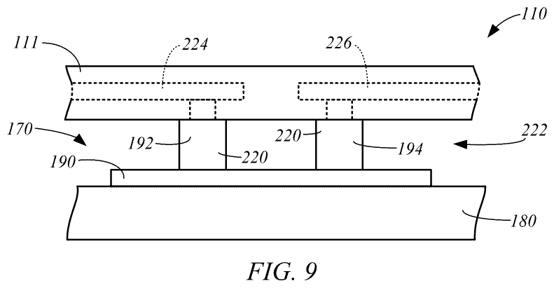

In some embodiments, the power regulator board 180 and the testing board 111 are stacked over each other as shown in FIGS. 7, 8 and 9. FIG. 9 is a simplified side view of a portion of the assembled burn-in board 110, in accordance with embodiments of the present disclosure. The testing board 111 may be stacked above the power regulator board as illustrated in FIGS. 7-9.

The power regulator board 180 may include a front edge 200, a back edge 202 that is opposite the front edge 200, and opposing side edges 204 and 206 that extend from the front edge 200 to the back edge 202, as shown in FIG. 7. The main power connector 180 may be located along the back edge 202. The testing board 111 may include edges that correspond to the edges of the power regulator board, including a front edge 210, a back edge 212 that is opposite the front edge 210, and opposing side edges 214 and 216 that extend from the front edge 210 to the back edge 212, as shown in FIG. 7. The testing stage connector 186 is located along the back edge 212.

While the example testing board of FIG. 7 includes twenty-four power supplies 190 configured to deliver the test power 164 to the testing board 111, it is understood that embodiments of the power regulator board 180 include more or fewer power supplies 190. In one example, the power supplies 190 are organized in rows around the perimeter of the power regulator board, such as along the front edge 200, the back edge 202, the side edge 204, and/or the side edge 206, as shown in FIG. 7. Advantages to this configuration include maximizing the real estate that is available for the electronics of the testing stage (e.g., testing boar 111) of the burn-in board 110.

In some embodiments, the test power connectors 192 and 194 of each power supply 190 may be arranged along the edges of the power regulator board 180, as shown in FIG. 7, and may each comprise a conductive stud 220 that extends vertically from the power regulator board 180 to the testing board 111, such as across a gap 222, as shown in FIG. 9. Each stud 220 connects to one of the conductive pathways of the testing board 111. The positive test power connectors 192 of multiple power supplies 190 may be connected in parallel through a conductive pathway 224 of the testing board 111 to increase the power that is supplied to a device testing unit. The corresponding negative or electrical ground test power connectors 194 of the multiple power supplies 190 may similarly be connected to each other in parallel through a conductive pathway 226.

The power regulator board 180 may also include one or more low power supplies 230 (FIG. 7) that may each be configured to provide supplemental power (e.g., 60 W) to circuitry of the testing board 111, such as circuitry for the I/O supply voltage of the semiconductor devices 104 under test. The low power supplies 230 may be located adjacent to the high power supplies 190. In some embodiments, the connectors 231 of the low power supplies 230 are located at the corners of the power regulator board 180.

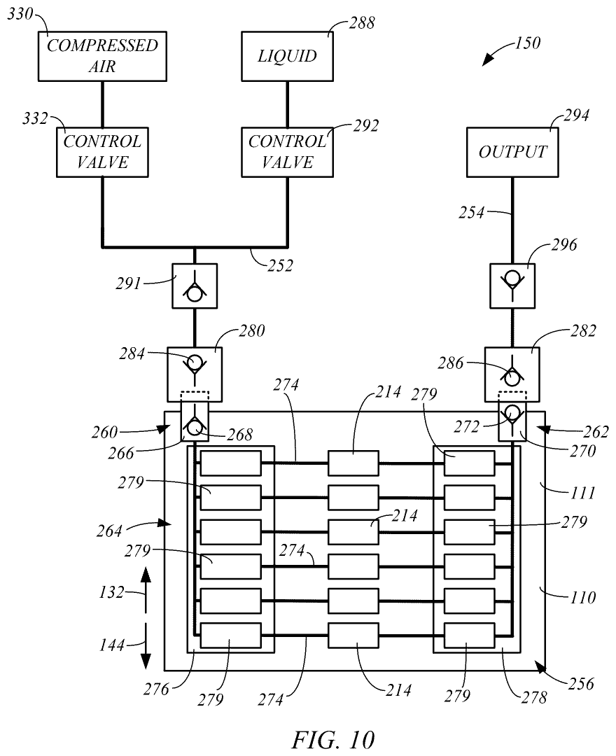

Embodiments of the present disclosure also relate to the heat exchange system 124 and, more specifically, to the cooling system 150 (FIG. 4), which operates to cool the semiconductor devices during stress test operations. FIG. 10 is a schematic diagram of an example of the cooling system 150, in accordance with embodiments of the present disclosure.

In some embodiments, the cooling system 150 facilitates automated coupling of a liquid feed line 252 and a liquid return line 254 to each of the burn-in boards 110 as they are installed in the chamber 108 of the semiconductor burn-in machine 102. Thus, the cooling system 150 highly simplifies the setup and operation of the machine 102 over hard-plumbed cooling systems of the prior art, which require time-consuming labor to connect the liquid feed and return lines to each of the burn-in boards.

The cooling system 150 is configured to route a flow of liquid (e.g., water) through the thermal heads 114 of the device testing units 112 to maintain the semiconductor devices 104 within a desired temperature range during the stress testing of the devices 104. The cooling system 150 includes a board cooling system 256 that is connected to a burn-in board 110, such as the testing board 111, having a plurality of device testing units 112, in accordance with one or more embodiments described above. The board cooling system 256 may be used with a burn-in board 110 that also includes a power regulator board 180 formed in accordance with one or more embodiments described above.

The board cooling system 256 generally comprises a liquid input 260, a liquid output 262 and a fluid circuit 264, as generally shown in FIG. 10. The liquid input 260 includes an input fitting 266 and a check valve 268, and the liquid output 262 includes an output fitting 270 and a check valve 272. The fluid circuit 264 generally comprises a plurality of fluid pathways 274 that deliver a flow of liquid received at the input fitting 266 through the thermal heads 114 and to the output fitting 270 where the liquid flow may be discharged.

The check valve 268, which may be a component of the input fitting 266, blocks liquid from being discharged through the liquid input 260 and is biased to require a flow of liquid at the liquid input 260 to overcome a threshold pressure before the flow can pass through the check valve 268 and to the fluid circuit 264. Similarly, the check valve 272, which may be a component of the output fitting 270, blocks liquid from flowing into the liquid output 262, and is biased to require a flow of liquid received from the fluid circuit 264 at the liquid output 262 to overcome a threshold pressure before the flow can be discharged from the liquid output 262.

The board cooling system 256 may also include an input manifold 276 that is configured to receive a flow of liquid through the input fitting 266 and deliver portions of the flow through output ports, each of which is connected to one of the fluid pathways 274. The board cooling system 256 may include an output manifold 278 that is configured to receive the flows from the fluid pathways 274 at corresponding input ports and deliver the flows to the output fitting 270.

In some embodiments, the input manifold 276 and/or the output manifold 278 includes a plurality of valves 279, each having an open state, in which a liquid flow is allowed to travel through the valve 279, and a closed state, in which liquid flow through the valve 279 is prevented. Each valve 279 of the input manifold 276 may control the flow of liquid through one of the manifold output ports, and each valve 279 of the output manifold 278 may control the flow of liquid through one of the manifold input ports.

In some embodiments, the valves 279 are controlled through control signals from a controller 120 of the system 100 or machine 102, such as the temperature controller 120A (FIG. 4). This allows for independent control of the flow of liquid through each thermal head 114 and the temperature of the semiconductor device 104 being tested by the corresponding device testing unit 112.

In some embodiments, the cooling system 150 includes a plurality of source fittings 280 and return fittings 282 that are supported by the machine housing 106, such as at the rear wall 136. Pairs of the source and return fittings 280, 282 are respectively configured to connect with the input and output fittings 266 and 270 of the board cooling system 256 of each board 110 when it is installed in the chamber 108, as indicated in FIG. 10. The source fitting 280 may have a corresponding check valve 284 and the return fitting 282 may have a check valve 286 to restrict the flow of liquid out of the source fitting 280 and into the return fitting 282.

The cooling system 150 may include a source of liquid 288 that is connected to the feed line or fluid pathway 252 connecting the liquid source 288 to the source fitting 280. A control valve 292 may be positioned in the fluid pathway 252 to open or close the fluid pathway 252, and a check valve 291 may limit the direction of the flow through the pathway 252. In some embodiments, the control valve 292 is in the form of a solenoid valve or another suitable valve and the open or closed state of the valve is controlled by control signals from a controller 120 of the system, such as the temperature controller 120A (FIG. 4), for example.

The return fitting 282 may be connected to an output 294 through the return line or fluid pathway 254, which may return liquid back to the source 288 or a collection reservoir, or direct the liquid to a drain, for example. A check valve 296 may be placed in the pathway 254 to prevent the backflow of liquid.

In some embodiments, the input fitting 266 and the output fitting 270 are oriented in the rearward direction 132, and the source fitting 280 and the return fitting 282 are oriented in the forward direction 144, as shown in FIGS. 8 and 10. This allows the input fitting 266 to mate with the source fitting 280 and the output fitting 270 to mate with the return fitting 282 when the burn-in board 100 is received in the chamber 108 of the machine and moved in the rearward direction 132, as discussed above with reference to FIGS. 2, 6A and 6B. During this mating of the fittings 266, 280 and 270 and 282, the connectors of the burn-in board, such as the testing stage connector 186 and the main power connector 182 (if present) are also connected to the corresponding connectors 188 and 184 of the machine electronics.

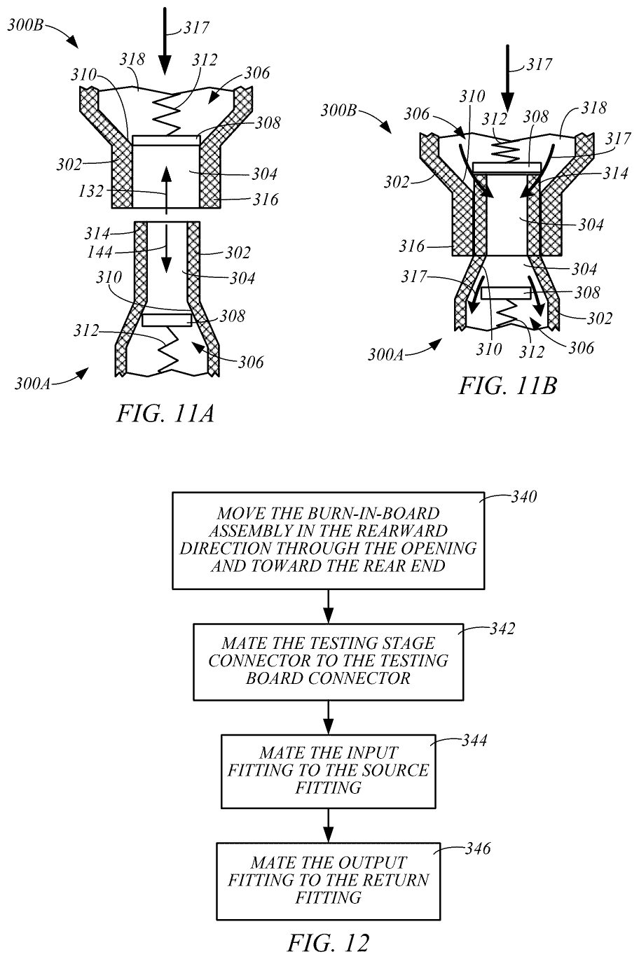

In some embodiments, the input fitting 266 and the source fitting 280, and the output fitting 270 and the return fitting 282 cooperate to open the corresponding check valves 268, 284 and 272, 286 and allow for a liquid flow to be delivered through the fluid circuit 264 of the board cooling system 256 when mated together. FIGS. 11A and 11B are simplified cross-sectional views of an example pair of cooperative male and female fittings 300A and 300B that may be used for the cooperating fittings 266, 280 and 270, 282 to facilitate this feature, in accordance with embodiments of the present disclosure. For example, the male fitting 300A could be used as the input fitting 266 and the return fitting 282 and the female fitting 300B could be used as the source fitting 280 and the output fitting 270, or vice versa.

Each of the fittings 300 includes a fitting body 302 having a flow channel 304, and a check valve 306 having a valve body 308 that is biased toward a valve seat 310 by a suitable biasing mechanism (e.g., spring) 312. A distal end 314 of the fitting body 302 of the male fitting 300A is configured to be received within the flow channel 304 of the distal end 316 of the female fitting 300B. When the fittings 300A and 300B are disconnected, as shown in FIG. 11A, the valve bodies 308 are biased against their valve seats 310 to seal the flow channels 304. Pressurized fluid 317 on the proximal side 318 of the valve body 308 of the female fitting 300A, such as at the source fitting 280, may also force the valve body 308 against the corresponding valve seat 310.

When the fittings 300A and 300B are mated together, as shown in FIG. 11B, the distal end 314 of the male fitting 300A displaces the valve body 308 of the female fitting 300B from its valve seat 310 and opens a fluid flow pathway around the valve body 308 and through the flow channel 304. This exposes the valve body 308 of the male fitting 300A to the pressurized fluid flow 317, which displaces the valve body 308 from the valve seat 310 and opens a fluid flow pathway around the valve body 308 and through the flow channel 304 of the fitting 300A. As a result, the pressurized fluid flow is allowed to travel through the flow channels 304 of the mated fittings 300A and 300B, as indicated in FIG. 11B.

In one embodiment, the fittings 300A and 300B do not latch together when mated (FIG. 11B). Rather, they are maintained in the mated state by the conventional mechanism that holds the burn-in board 110 in its installed state within the chamber 108.

When the fittings 300A and 300B are disconnected from each other (FIG. 11A), such as when the burn-in board 110 is moved from the installed state (FIG. 6A) in the forward direction 144 to the deinstalled state (FIG. 6B), the distal end 314 of the male fitting 300A is withdrawn from the flow channel 304 of the female fitting 300B, and the check valves 306 close the flow channels 304, thereby preventing fluid from leaking through the fittings 300A and 300B, as shown in FIG. 11A.

In some embodiments, the burn-in board 110 includes a tray 320 (FIG. 7) that is configured to collect any liquid drops that may fall during the coupling or decoupling of the input fitting 266 and the source fitting 280, and the output fitting 270 and the return fitting 282. The tray 320 may be attached to the power regulator board 180, and may comprise one or more drip collector reservoirs, 322. In one example, the input fitting 266, the output fitting 270, the input manifold 276, the output manifold 278, and/or the valves 279, are located outside the side edge 214 of the testing board 111, and the reservoirs 222 are located directly beneath the valving 279 and the input and output fittings 266, 270 along the edge 204 of the power regulator board 180, as shown in FIG. 7. This arrangement displaces potential leak sources away from the high power circuitry of the testing board 111 and the power regulator board 180.

Additional embodiments of the cooling system 150 relate to features that further reduce the likelihood of a liquid leak at the liquid input 260, the liquid output 262, the source fitting 280 and the return fitting 282 during deinstallation of the burn-in boards 110 from the chamber 108 of the machine 102. In one embodiment, the cooling system 150 includes a source of compressed air 330 that is used to blow out the liquid in the fluid circuit 264 of each of the burn-in boards 110 prior to deinstalling the burn-in boards 110.

The source of compressed air 330 is connected to the source fitting 280. This connection may be through a control valve 332 and one or more check valves, such as the check valve 291 and the check valve 284 of the source fitting 280, for example. A blowout of the liquid in the fluid circuit 264 of the board cooling system 256 may be performed by closing the liquid control valve 292 and opening the air control valve 332. This connects a pressurized flow of air to the mated source fitting 280 and input fitting 266. If present, the valving 279 may be opened to allow the flow of air to travel through fluid pathways 274, the thermal heads 214, the output fitting 270 and the return fitting 282 to blow out the liquid in the board cooling system 256. After a period of time (e.g., 10 seconds), which may be predetermined, after most of the liquid has been discharged to the output 294, the air control valve 332 is closed to stop the airflow. The burn-in board 110 may then be deinstalled from the machine 102 by moving the board 110 in the forward direction 144 relative to the housing 106, which disconnects the various connections. Due to the air blowout, the likelihood of any liquid dripping from the input fitting 266, the output fitting 270, the source fitting 280 or the return fitting 282 is very low.

FIG. 12 is a flowchart illustrating a method of installing a burn-in board 110 in a semiconductor burn-in machine 102, in accordance with embodiments of the present disclosure. At 340, a burn-in board 110 formed in accordance with one or more embodiments of the present disclosure, is moved in the rearward direction 132 through the opening 134 of the chamber 108 and toward the rear wall 136 of the housing 106 (see FIG. 6B). This may involve mounting the burn-in board 110 to a pair of the slide rails 142 (FIGS. 1 and 2) as discussed above, and guiding the rearward movement of the burn-in board 110 using the slide rails 142. The testing stage connector 186 is mated to the testing board connector 188 at 342, the input fitting 166 is mounted to the source fitting 180 at 344, and the output fitting 270 is mounted to the return fitting 282 at 346, in response to the rearward movement of the board 110 in step 340. The door 140 (FIG. 2) of the machine may be moved to a closed position to cover the opening 134 to the chamber before stress testing operations begin on the installed burn-in board 110. When the burn-in board includes the power regulator board 180, the main power connector 182 is connected to the machine power connector 184 in response to step 340.

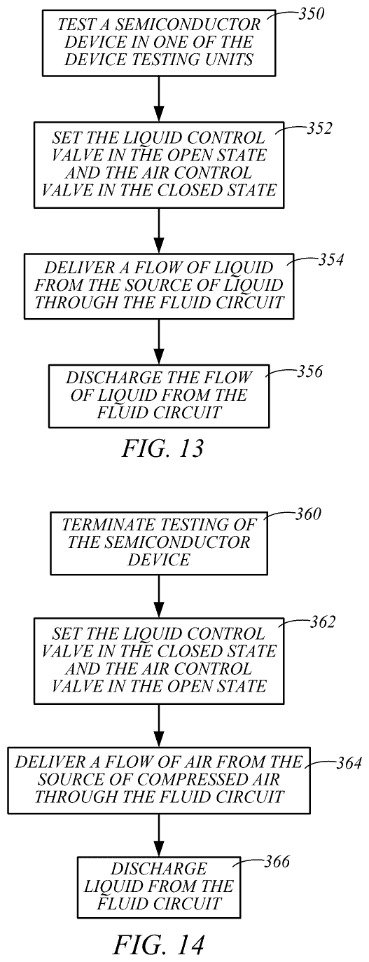

FIG. 13 is a flowchart illustrating a method of operating a semiconductor burn-in machine 102, in accordance with embodiments of the present disclosure. After the burn-in board 110 is installed in the machine 102 (FIGS. 1 and 6A), at 350 a test is performed on one or more of the semiconductor devices 104 installed in the device testing units 112 on the board 110. At 352, the liquid control valve 292 is set to the open state and the air control valve 332 (if present) is set to the closed state. It is understood that step 352 may be performed before, simultaneously with, or after the performance of step 350.

At 354, a flow of liquid is delivered from the source of liquid 288 through the liquid input 260, the fluid circuit 264 and the thermal heads 114. The flows of liquid to the thermal heads 114 may be controlled as described above, such as using the corresponding valve 279, and is used to control the temperature of the semiconductor devices 104 being tested. The flow of liquid is then discharged through the output fitting 270 and the return fitting 282 to the output 294, at 356.

After the method of FIG. 13, a blowout operation may be performed, an example of which is illustrated in the flowchart of FIG. 14. At 360, the testing of the semiconductor device 104 (step 350) is terminated. At 362, the liquid control valve 292 is set to the closed state and the air control valve 332 is set to the open state. At 364, a flow of air from the source of compressed air 330 is delivered through the fluid circuit 264 of the board cooling system 256. In some embodiments, this involves delivering the flow of air through the source fitting 280, the input fitting 266, the valving 279, the output fitting 270 and/or the return fitting 282, for example. At 366, the liquid in the fluid circuit 264 is discharged to the output 294 using the air flow. The air control valve 332 may then be closed to stop the flow of air, such as after a predetermined period of time. The burn-in board 110 may then be deinstalled from the machine 102 by moving the burn-in board 110 in the forward direction 144 relative to the housing 106, as mentioned above.

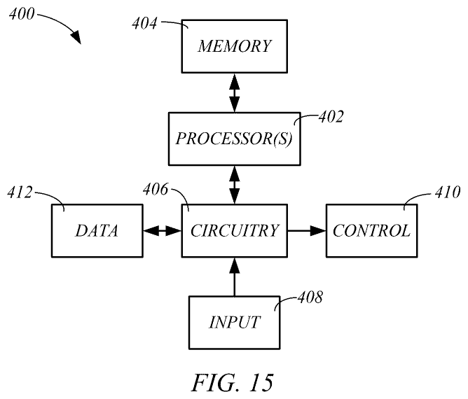

The one or more controllers 120 of the system, such as, for example, the temperature controller 120A and the test vector controller 120B, may take on any suitable form to control the various functions described herein, such as that of the example controller 400 shown in the simplified diagram of FIG. 15. The controller 400 may include one or more processors 402 and memory 404. The one or more processors 402 are configured to perform various functions described herein in response to the execution of instructions contained in the memory 404.

The one or more processors 402 may be components of one or more computer-based systems, and may include one or more control circuits, microprocessor-based engine control systems, and/or one or more programmable hardware components, such as a field programmable gate array (FPGA). The memory 404 represents local and/or remote memory or computer readable media. Such memory 404 comprises any suitable patent subject matter eligible computer readable media and does not include transitory waves or signals. Examples of the memory 404 include conventional data storage devices, such as hard disks, CD-ROMs, optical storage devices, magnetic storage devices and/or other suitable data storage devices. The controller 400 may include circuitry 406 for use by the one or more processors 402 to receive input signals 408 (e.g., signals from I/O pins 174, temperature sensing circuit 156, etc.), issue control signals 410 (e.g., signals for controlling the heat exchange system 124, performing tests on semiconductor devices 104, controlling the power supplies 190, etc.) and/or communicate data 412, such as in response to the execution of the instructions stored in the memory 404 by the one or more processors 202.

Although the embodiments of the present disclosure have been described with reference to preferred embodiments, workers skilled in the art will recognize that changes may be made in form and detail without departing from the spirit and scope of the present disclosure.

What is claimed is:

1. A burn-in board configured for insertion into a chamber of a semiconductor burn-in machine, the burn-in board comprising:
a testing board comprising:
a plurality of device testing units, each configured to apply test signals to a received semiconductor device under test and including a thermal head; and
a testing stage connector, through which the test signals are communicated to the device testing units, located adjacent a back edge of the testing board and facing in a rearward direction; and
a board cooling system comprising:
a liquid input including an input fitting oriented in the rearward direction and a check valve;
a liquid output including an output fitting oriented in the rearward direction and a check valve; and
a fluid circuit comprising a plurality of fluid pathways configured to deliver a flow of liquid received at the liquid input through the thermal heads and to the liquid output.

2. The burn-in board according to claim 1, wherein the board cooling system comprises:
an input manifold configured to receive the flow of liquid through the input fitting, the input manifold comprising a plurality of output ports, each configured to discharge a portion of the flow of liquid to one of the fluid pathways; and
an output manifold configured to discharge the flow of liquid through the output fitting, the output manifold comprising a plurality of input ports, each configured to receive one of portions of the flow of liquid from one of the fluid pathways.

3. The burn-in board according to claim 2, wherein:
the input manifold includes a plurality of valves, each configured to control one of the portions of the flow of liquid through one of the output ports; and/or
the output manifold includes a plurality of valves, each configured to control one of the portions of the flow of liquid through one of the input ports.

4. The burn-in board according to claim 3, wherein each of the valves is controlled by control signals received through the testing stage connector.

5. The burn-in board according to claim 1, including a tray supporting the testing board, the liquid input and the liquid output.

6. The burn-in board according to claim 1, including:
a power regulator board connected to the testing board comprising:
a main power connector configured to receive main power from a semiconductor burn-in machine, located adjacent a back edge of the power regulator board and facing in the rearward direction;
a plurality of power supplies each configured to receive the main power from the main power connector and convert the main power to test power; and
a pair of test power connectors for each power supply,
wherein each device testing unit is configured to receive the test power from at least one of the power supplies through at least one pair of the test power connectors.

7. The burn-in board according to claim 6, including a tray supporting the power regulator board, the tray including a drip collector reservoir located beneath the liquid input and liquid output and configured to collect liquid drops leaked from the liquid input or the liquid output.

8. The burn-in board according to claim 6, wherein the test power has a test voltage that is less than a main voltage of the main power.

9. The burn-in board according to claim 1, wherein:
the input fitting is configured to mate with a corresponding source fitting of a semiconductor burn-in machine and establish a fluid flow pathway therebetween; and
the output fitting is configured to mate with a corresponding return fitting of the semiconductor burn-in machine and establish a fluid flow pathway therebetween.

10. The burn-in board according to claim 9, wherein:
the input fitting is configured to mate with the corresponding source fitting of the semiconductor burn-in machine without latching to the source fitting; and
the output fitting is configured to mate with the corresponding return fitting of the semiconductor burn-in machine without latching to the return fitting.

11. A semiconductor burn-in system comprising:
a semiconductor burn-in machine including:
a housing comprising a chamber having an opening at a front end and a rear end that is opposite the front end;
a plurality of testing board connectors, each located at the rear end of the chamber and oriented in a forward direction, which is toward the front end; and
a plurality of liquid connectors, each including:
a source fitting at the rear end oriented in the forward direction; and
a return fitting at the rear end oriented in the forward direction; and
a plurality of burn-in-boards, each configured to be installed in the chamber through the opening and comprising:
a testing board comprising:
a plurality of device testing units, each configured to apply test signals to a received semiconductor device under test and including a thermal head; and
a testing stage connector located adjacent a back edge of the testing board and oriented in a rearward direction that is opposite the forward direction, the testing stage connector configured deliver the test signals to the device testing units; and
a board cooling system comprising:
a liquid input including an input fitting oriented in the rearward direction and a check valve;
a liquid output including an output fitting oriented in the rearward direction and a check valve; and
a fluid circuit comprising a plurality of fluid pathways configured to deliver a flow of liquid received at the liquid input through the thermal heads and to the liquid output.

12. The system according to claim 11, wherein:
each input fitting is configured to mate with one of the source fittings and establish a fluid flow pathway therebetween; and
each output fitting is configured to mate with one of the corresponding return fittings and establish a fluid flow pathway therebetween.

13. The system according to claim 12, wherein:
each input fitting is configured to mate with one of the source fittings without latching to the source fitting; and
each output fitting is configured to mate with one of the corresponding return fittings without latching to the return fitting.

14. The system according to claim 12, wherein:
an input manifold configured to receive the flow of liquid through the input fitting, the input manifold comprising a plurality of output ports, each configured to discharge a portion of the flow of liquid to one of the fluid pathways; and
an output manifold configured to discharge the flow of liquid through the output fitting, the output manifold comprising a plurality of input ports, each configured to receive one of portions of the flow of liquid from one of the fluid pathways.

15. The system according to claim 14, wherein:
the input manifold includes a plurality of valves, each configured to control one of the portions of the flow of liquid through one of the output ports; and/or
the output manifold includes a plurality of valves, each configured to control one of the portions of the flow of liquid through one of the input ports.

16. The system according to claim 11, wherein each burn-in board includes a tray supporting the testing board, the liquid input and the liquid output.

17. The system according to claim 11, including:
a source of liquid;
a liquid control valve configured to open and close a fluid pathway between the source of liquid and the source fitting;
a source of compressed air; and
an air control valve configured to open and close a fluid pathway between the source of compressed air and the source fitting.

18. The system according to claim 11, wherein each burn-in board includes:
a power regulator board connected to the testing board comprising:
a main power connector configured to receive main power from a semiconductor burn-in machine, located adjacent a back edge of the power regulator board and facing in the rearward direction;
a plurality of power supplies each configured to receive the main power from the main power connector and convert the main power to test power; and
a pair of test power connectors for each power supply,
wherein each device testing unit is configured to receive the test power from at least one of the power supplies through at least one pair of the test power connectors.

19. The system according to claim 18, wherein each burn-in board includes a tray supporting the power regulator board, the tray including a drip collector located beneath the liquid input and liquid output and configured to collect liquid drops leaked from the liquid input or the liquid output.

20. The system according to claim 18, wherein the test power has a test voltage that is less than a main voltage of the main power.

21. The system according to claim 11, wherein the chamber includes a plurality of guide rail pairs, each configured to support one of the burn-in boards in the chamber and guide rearward movement of the burn-in board relative to the housing during installation of the burn-in board into the chamber such that the testing stage connector mates with one of the testing board connectors, the input fitting mates with one of the source fittings, and the output fitting mates with one of the return fittings.

22. A method of operating a semiconductor burn-in system, which includes:
a semiconductor burn-in machine including:
a housing comprising a chamber having an opening at a front end and a rear end that is opposite the front end;
a plurality of testing board connectors, each located at the rear end of the chamber and oriented in a forward direction, which is toward the front end; and
a plurality of liquid line connectors, each including:
a source fitting at the rear end oriented in the forward direction; and
a return fitting at the rear end oriented in the forward direction; and
a burn-in-board comprising:
a testing board comprising:
a plurality of device testing units, each configured to apply test signals to a received semiconductor device under test and including a thermal head; and
a testing stage connector located adjacent a back edge of the testing board and oriented in a rearward direction that is opposite the forward direction, the testing stage connector configured deliver the test signals to the device testing units; and
a board cooling system comprising:
a liquid input including an input fitting oriented in the rearward direction and a check valve;
a liquid output including an output fitting oriented in the rearward direction and a check valve; and
a fluid circuit configured to deliver a flow of liquid received at the liquid input through the thermal heads and to the liquid output,
the method comprising installing the burn-in-board in the chamber comprising:
moving the burn-in-board in the rearward direction through the opening and toward the rear end; and
in response to the moving:
mating the testing stage connector to the testing board connector;
mating the input fitting to the source fitting; and
mating the output fitting to the return fitting.

23. The method of claim 22, wherein:
mating the input fitting to the source fitting occurs without latching the input fitting to the source fitting; and
mating the output fitting to the return fitting occurs without latching the output fitting to the return fitting.

24. The method of claim 23, wherein:
the system includes:
a source of liquid;
a liquid control valve having an open state in which the source of liquid and the source fitting are fluidically connected and a closed state in which the source of liquid and the source fitting are fluidically disconnected;
a source of compressed air; and
an air control valve having an open state in which the source of compressed air and the source fitting are fluidically connected and a closed state in which the source of compressed air and the source fitting are fluidically disconnected; and
the method comprises:
testing a semiconductor device in a first of the device testing units; and
cooling the semiconductor device comprising:
setting the liquid control valve in the open state;
setting the air control valve in the closed state;
delivering a flow of liquid from the source of liquid through the input fitting, the thermal head of the first device testing unit and the fluid circuit; and
discharging the flow of liquid through the output fitting.

25. The method of claim 24, further comprising:
terminating the testing of the semiconductor device; and
blowing out the liquid including:
setting the liquid control valve in the closed state;
setting the air control valve in the open state;
delivering a flow of air from the source of compressed air through the input fitting, the thermal head, the fluid circuit and the output fitting;
discharging liquid from the output fitting in response to delivering the flow of air; and
setting the air control valve in the closed state;
moving the burn-in board in the forward direction relative to the housing; and
disconnecting the testing stage connector from the testing board connector, the input fitting from the source fitting, and the output fitting from the return fitting, in response to moving the burn-in board.
